(19) United States
(12) Patent Application Publication
(10) Pub. No.: US 2019/0115523 A1
(43) Pub. Date: Apr. 18, 2019

(54) POWER GENERATION DEVICE

(71) Applicant: Panasonic Intellectual Property Management Co., Ltd., Osaka (JP)

(72) Inventors: SUGURU OHISHI, Okayama (JP); KOHEI FUDO, Osaka (JP)

(21) Appl. No.: 16/088,476

(22) PCT Filed: Apr. 26, 2017
(86) PCT No.: PCT/JP2017/016517

§ 371 Date: Sep. 26, 2018

(30) Foreign Application Priority Data
Jul. 12, 2016 (JP) 2016-137294

(51) Int. Cl. H01L 41/113; H02N 2/18

(52) U.S. Cl. CPC H01L 41/1136; H02N 2/181

(57) ABSTRACT

A power generation device includes a power generator and an activator. The power generator includes a piezoelectric element and a first attraction part provided on the piezoelectric element. The piezoelectric element generates power by vibration. The activator warps the piezoelectric element by moving a second attraction part attractingly contacting the first attraction part from a first position to a second position. The piezoelectric element warped by the activator vibrates when attractingly contacting between the first attraction part and the second attraction part is released. The second attraction part of the activator moves to the second position separated from the first attraction part when attractingly contacting of the first attraction part is released. The activator moved to the second position returns to the first position by magnetic attraction force while the first attraction part and the second attraction part are separated away from each other.

### TECHNICAL FIELD

The present disclosure relates to a power generation device built in various electronic devices.

### BACKGROUND ART

A conventional power generation device will be described below. The conventional power generation device includes a case, a power generator, activator, and a return spring. The power generator includes a piezoelectric element. One end of the piezoelectric element is connected with the case so that the piezoelectric element is held in a cantilever state. The power generator generates electric power by vibration of the piezoelectric element. The activator is held vertically movably by the case. The activator moves downward to apply a load to warp the piezoelectric element, and then, releases the load so as to vibrate the piezoelectric element. The activator that has moved downward moves upward and returns to its original position by the return spring. In other words, the conventional power generation device is configured to return the activator to the original position by the return spring.

For example, PTL1 discloses the prior art related to the present disclosure.

### CITATION LIST

### Patent Literature

PTL1: Japanese Patent Laid-Open Publication No. 2004-201376

### SUMMARY

A power generation device of the present disclosure includes a power generator and an activator. The power generator includes a piezoelectric element and a first attraction part provided on the piezoelectric element. The piezoelectric element generates electric power due to vibration. The activator includes a second attraction part configured to attractingly contact the first attraction part by a magnetic attraction force. The activator warps the piezoelectric element by moving the second attraction part from a first position at which the second attraction part attractingly contacts the first attraction part, to a second position. The piezoelectric element warped by the activator vibrates when the attractingly contacting between the first attraction part and the second attraction part is released. The second attraction part of the activator moves to the second position separated away from the first attraction part when the attractingly contacting of the first attraction part is released. The activator moved to the second position returns to the first position by a magnetic attraction force applied while the first attraction part and the second attraction part are separated away from each other. In other words, the activator returns to its original position by the magnetic attraction force while the first attraction part and second attraction part are separated away from each other.

### BRIEF DESCRIPTION OF DRAWINGS

FIG. 1 is a front view of a power generation device in accordance with an exemplary embodiment of the present disclosure.

FIG. 2 is a sectional view of the power generation device along line 2-2 shown in FIG. 1.

FIG. 3 is a sectional view of the power generation device along line 3-3 shown in FIG. 1.

FIG. 4 is an exploded perspective view of the power generation device shown in FIG. 1.

FIG. 5 is an exploded perspective view of the power generation device shown in FIG. 1.

FIG. 6 illustrates a modification example of the power generation device of the present disclosure.

### DETAIL DESCRIPTION OF PREFERRED EMBODIMENTS

Prior to description of an exemplary embodiment of the present disclosure, a disadvantage of a conventional power generation device will be briefly described below.

The conventional power generation device includes the return spring to return the activator to its original position. Thus, the conventional power generation device requires the return spring and also requires a space for accommodating the return spring therein. This configuration increases the size of the power generation device.

In a power generation device according to the present disclosure, an activator returns to its initial position (first position) by a magnetic attraction force between the first attraction part and the second attraction part, thus requiring no return spring. Accordingly, no space for accommodating the return spring is necessary. This configuration reduces the size of the power generation device.

The power generation device in accordance with the exemplary embodiment of the present disclosure will be detailed below with reference to drawings.

### Exemplary Embodiment

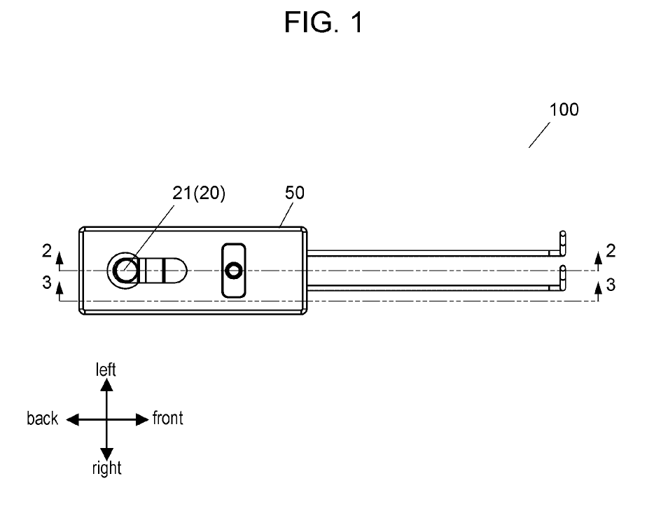

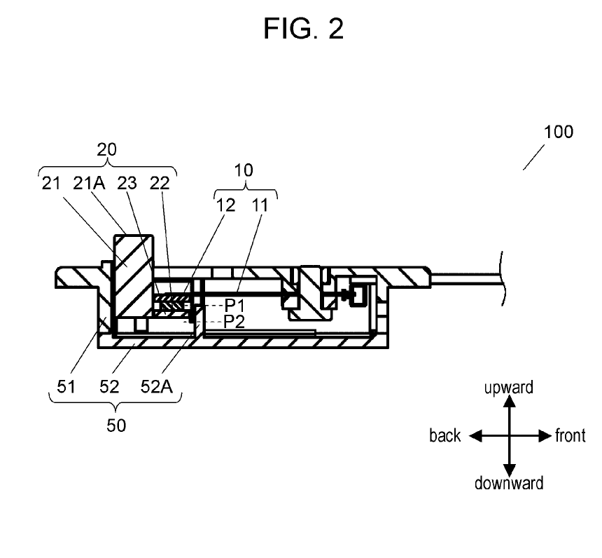

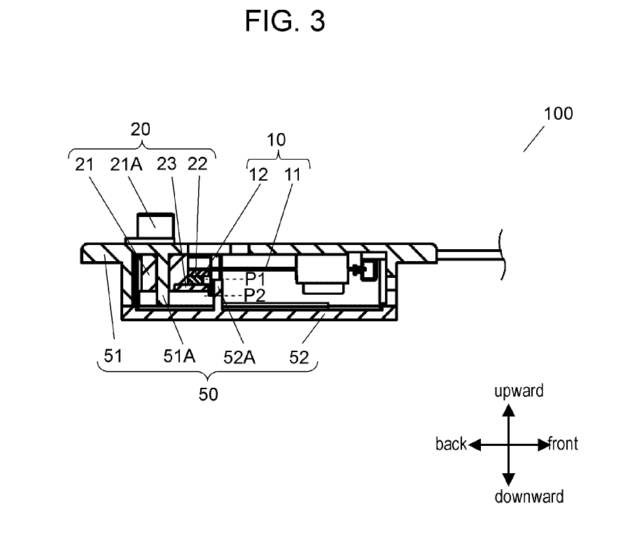

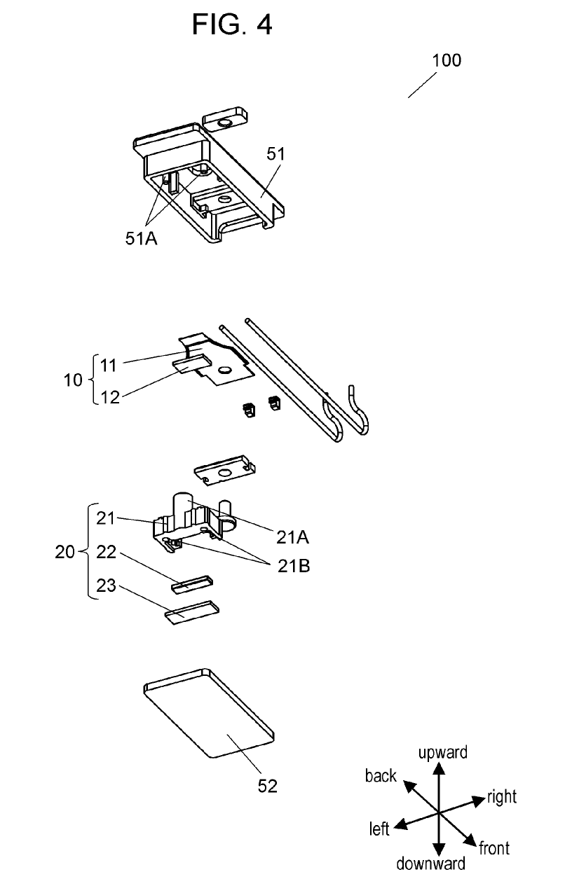

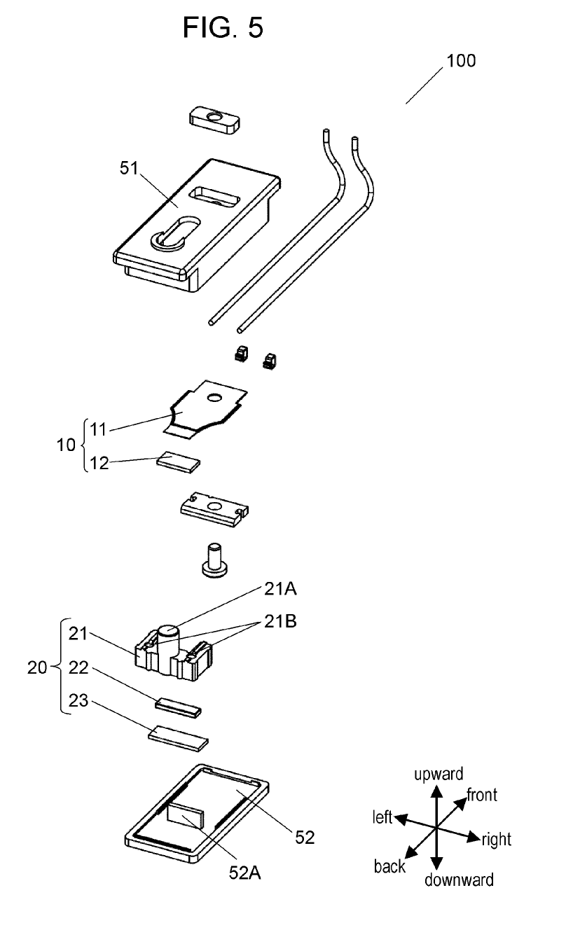

FIG. 1 is a front view of power generation device 100. FIG. 2 is a sectional view of power generation device 100 along line 2-2 shown in FIG. 1. FIG. 3 is a sectional view of power generation device 100 along line 3-3 shown in FIG. 1. FIG. 4 and FIG. 5 are exploded perspective views of power generation device 100.

As typically shown in FIG. 2, power generation device 100 includes case 50, power generator 10, and activator 20. Power generator 10 includes piezoelectric element 11 fixed with a cantilever structure, and first attraction part 12 provided at a tip of piezoelectric element 11. Power generator 10 generates electric power by vibration of piezoelectric element 11. Activator 20 includes body part 21 and second attraction part 22. Activator 20 is held vertically movably by case 50. Second attraction part 22 is held by body part 21. Second attraction part 22 is thus vertically movable together with body part 21 by case 50. The vertical direction does not necessary limits the direction of installing power generation device 100. Second attraction part 22 faces first attraction part 12 of power generator 10. At least one of first attraction part 12 and second attraction part 22 is a magnet. Accordingly, second attraction part 22 is configured to attractingly contact first attraction part 12 by a magnetic attraction force.

For example, when an operator applies a load in a first direction (downward direction) to activator 20, activator 20 moves downward. In other words, activator 20 moves downward by receiving a load from outside. In accordance with the movement of activator 20, second attraction part 22 moves from first position P1 to second position P2 below first position P1. First position P1 is a position at which second attraction part 22 attractingly contacts first attraction part 12. Second attraction part 22 attractingly contacts first attraction part 12 by the magnetic attraction force, and thus second attraction part 22 moves downward while being attached to first attraction part 12. In other words, piezoelectric element 11 warps as a tip of piezoelectric element 11 moves downward in accordance with the downward movement of activator 20. Then, when a return force produced by downward warpage of piezoelectric element 11 becomes greater than the magnetic attraction force, first attraction part 12 separates away from second attraction part 22 so as to cause piezoelectric element 11 to start vibrating. In other words, piezoelectric element 11 warped downward vibrates by releasing the attractingly contacting between second attraction part 22 and first attraction part 12 provided at the tip of piezoelectric element 11.

Second attraction part 22 reaches second position P2 separated away from first attraction part 12 by releasing the attractingly contacting of first attraction part 12. Since second attraction part 22 moved to second position P2 receives a force in a second direction (upward direction) opposite to the first direction (downward direction) by the magnetic attraction force, although separated from first attraction part 12, second attraction part 22 moves upward when the downward load applied to activator 20 is released. In other words, the downward movement of activator 20 is restricted by lower case 52 of case 50, and thus second attraction part 22 is located at second position P2 when activator 20 reaches a position at which the downward movement is restricted by lower case 52. The position of activator 20 at which the downward movement is restricted by lower case 52 is, for example, the lowest position in the vertical movement of activator 20. Although activator 20 is located at the lowest position, the attraction force capable of pushing up activator 20 acts between first attraction part 12 and second attraction part 22. Accordingly, the second attraction part moved to second position P2 returns to its original position (first position P1) by the magnetic attraction force while first attraction part 12 and second attraction part 22 are separated away from each other. In other words, the activator moved to second position P2 by an external load returns to its original position (first position P1) by the magnetic attraction force while the first attraction part and the second attraction part are separated away from each other.

As described above, since activator 20 moved to second position P2 returns to first position P1 by the magnetic attraction force between first attraction part 12 and second attraction part 22, power generation device 100 does not require a return spring to return activator 20 to first position P1. Power generation device 100 thus does not require a space accommodating the return spring therein, accordingly reducing the size of power generation device 100.

Since power generation device 100 does not require the return spring, no repulsive force of the return spring is applied downward on moving activator 20. Accordingly, the operator can move activator 20 downward with a small load. In other words, an external load required for generating electric power by power generation device 100 can be reduced.

Power generation device 100 will be detailed below.

As described above, power generation device 100 includes case 50, power generator 10, and activator 20. Power generator 10 and activator 20 are accommodated in case 50. Apart of activator 20 is exposed from case 50. Case 50 includes upper case 51 and lower case 52. Both upper case 51 and lower case 52 are made of resin material to configure case 50 by bonding, typically welding. This configuration reduces the number of components. As shown in FIG. 4, two guide pins 51A having circular columnar shapes protruding downward are formed on upper case 51. A through-hole is provided in upper casting 51. A part of activator 20 is exposed from the through-hole, as typically shown in FIG. 3. Limiter 52A protrudes upward from lower case 52.

Power generator 10 includes piezoelectric element 11 and first attraction part 12 disposed on one end of piezoelectric element 11. The other end of piezoelectric element 11 opposite to the end having first attraction part 12 is provided thereon is bonded to upper case 51. In other words, piezoelectric element 11 has a cantilever structure in which the end piezoelectric element 11 at the side of first attraction part 12 is a free end. Piezoelectric element 11 is a thin sheet made of piezoelectric material provided on a thin metal sheet, and generates electric power by deformation, such as vibration. The metal sheet is preferably made of metal material, such as stainless steel, with a spring property. The piezoelectric material is preferably formed on both surfaces of the metal sheet so as to increase the amount of the generated power. The piezoelectric material may be formed only on one surface of the metal sheet. First attraction part 12 is a cuboid member made of magnetic material, and attractingly contacts second attraction part 22 of activator 20, which is described later, by magnetic force.

Activator 20 includes body part 21, second attraction part 22, and yoke 23. As shown in FIG. 4, two guide holes 21B are provided in body part 21. Guide pins 51A of upper case 51 are inserted into guide holes 21B, respectively. Activator 20 is thus held vertically movably. A part of body part 21 protrudes from the through-hole provided in upper case 51 to constitute button 21A. Second attraction part 22 is a cuboid member made of a magnet, and is held by body part 21. As typically shown in FIG. 3, when second attraction part 22 is located at first position P1, the upper surface of second attraction part 22 attractingly contacts the lower surface of first attraction part 12. Yoke 23 is made of a magnetic material disposed below second attraction part 22. The activator may not necessarily include yoke 23.

Second attraction part 22 may be formed of magnetic material. In this case, first attraction part 12 is made of a magnet. As long as first attraction part 12 and second attraction part 22 attractingly contact each other by a magnetic attraction force, one of first attraction part 12 and second attraction part 22 may be made of a magnet while the other of first attraction part 12 and second attraction part 22 is made of magnetic material. Both first attraction part 12 and second attraction part 22 may be made of magnet. In this case, magnetic polarities of first attraction part 12 and second attraction part 22 are determined to allow the attraction parts to attractingly contact each other.

Power generation device 100 is configured as described above. An operation of power generation device 100 will be described below.

When an operator applies a load to button 21A of activator 20 downward during, e.g. the state shown in FIG. 2, activator 20 moves downward. In other words, second attraction part 22 moves downward from first position P1 at which second attraction part 22 attractingly contacts first attraction part 12, as shown in FIG. 2, in accordance with movement of activator 20. At this moment, second attraction part 22 attractingly contacts first attraction part 12 by a magnetic attraction force, and thus, second attraction part 22 moves downward while still attachingly contacting first attraction part 12. In other words, a tip of piezoelectric element 11 warps downward in accordance with the downward movement of activator 20. When the return force of piezoelectric element 11 produced by the downward warpage exceeds the magnetic attraction force, first attraction part 12 of piezoelectric element 11 is separated, i.e., removed away from second attraction part 22 of activator 20, thereby causing piezoelectric element 11 to start vibrating. In other words, activator 20 applies a load to piezoelectric element 11 by a magnetic attraction force, and warps piezoelectric element 11 downward. Then, piezoelectric element 11 vibrates when the attracting contacting between first attraction part 12 and second attraction part 22 is released while piezoelectric element 11 is warped. Piezoelectric element 11 generates an alternating-current (AC) electric power by this vibration.

When the operator presses button 21A, the operator receives the return force produced by the warpage of piezoelectric element 11 until the attractingly contacting between first attraction part 12 and second attraction part 22 is released. In other words, the operator receives a force pushing up button 21A. When the attractingly contacting between first attraction part 12 and second attraction part 22 is released, activator 20 is released from the return force produced by the warpage of piezoelectric element 11, accordingly decreasing the force pushing up button 21A. The operator thus obtains a tactile feedback.

Power generation device 100 preferably includes limiter 52A, as typically shown in FIG. 2. Limiter 52A is a cuboid member protruding upward from the upper surface of lower case 52. A tip of the limiter protruding upward faces the lower surface of piezoelectric element 11 with a predetermined distance between the tip of the limiter and the lower surface of piezoelectric element 11. Limiter 52A is configured to contact the lower surface of piezoelectric element 11 when piezoelectric element 11 warps by a predetermined warpage amount. In other words, limiter 52A restricts the warpage of piezoelectric element 11.

In power generation device 100 including limiter 52A, the attractingly contacting between first attraction part 12 and second attraction part 22 is released while a warpage amount of piezoelectric element 11 warped downward is restricted. Accordingly, variations in warpage amount of piezoelectric element 11 can be suppressed when attractingly contacting between first attraction part 12 and second attraction part 22 is released. In other words, variations of amplitude of the vibration of piezoelectric element 11 in the above power generation can be suppressed. This configuration stabilizes the amount of the power generated by power generation device 10. In the power-generating operation, a load required for vibrating piezoelectric element 11 becomes constant, and thus variations of tactile feedback that the operator obtains on pressing button 21A of activator 20, for example, can be reduced.

Power generation device 100 does not necessary include limiter 52A. In this case, the return force of piezoelectric element 11 increases as the warpage amount of piezoelectric element 11 increases. When the return force becomes greater than the magnetic attraction force, attractingly contacting between first attraction part 12 and second attraction part 22 is released, and piezoelectric element 11 vibrates.

Then, second attraction part 22 is separated away from first attraction part 12 when the attractingly contacting between second attraction part 22 and first attraction part 12 is released. In other words, second attraction part 22 moves to second position P2 separated away from first attraction part 12. Second attraction part 22 moved to second position P2 is separated away from first attraction part 12, but second attraction part 22 receives the upward force due to magnetic attraction force while first attraction part 12 and second attraction part 22 are separated away from each other. Accordingly, when the downward load applied to activator 20 by the operator is released, second attraction part 22 moves upward by the magnetic attraction force. In other words, activator 20 moved to second position P2 returns to its original position (first position P1) by the magnetic attraction force while first attraction part 12 and second attraction part 22 are separated away from each other.

As described above, in power generation device 100, activator 20 moved to second position P2 returns to first position P1 by the magnetic attraction force acting on first attraction part 12 and second attraction part 22. Therefore, activator 20 requires no return spring for returning activator 20 to first position P1. A space for accommodating the return spring there is not necessary, and thus, power generation device 100 may have a small size.

As described above, case 50 is preferably made of resin material so as to suppress influence on the magnetic force generated between first attraction part 12 and second attraction part 22. However, case 50 is not necessarily entirely made of resin material. For example, as long as the magnetic attraction force between first attraction part 12 and second attraction part 22 and vibration of piezoelectric element 11 are not hindered, a part of case 50 may be made of metal material.

Body part 21 is preferably made of resin material. This configuration reduces the weight of activator 20. This configuration allows activator 20 to be returned to its original position (first position P1) promptly by attraction force between first attraction part 12 and second attraction part 22. A resin material is also preferable because it is a nonmagnetic material and can thus suppress influence on the magnetic force generated between first attraction part 12 and second attraction part 22. The resin material is preferable since it can suppress influence on vibration of power generator 10.

In activator 20, body part 21 may not necessarily be made of resin material. All or a part of body part 21 may be made of metal material. In this case, the metal material is preferably nonmagnetic material, such as aluminum, with specific gravity smaller than second attraction part 22 for body part 21. Body part 21 is not necessarily made of nonmagnetic material, and may be made of magnetic material. In this case, first attraction part 12 of power generator 10 is preferably a magnet. This configuration allows body part 21 to function as second attraction part 22. Body part 21 and second attraction part 22 of activator 20 may be the unitarily formed.

When second attraction part 22 is made of a magnet, activator 20 preferably includes yoke 23. Yoke 23 is made of a magnetic material configured to attractingly contact second attraction part 22, and disposed on a surface (bottom face) of second attraction part 22 opposite to the upper surface of second attraction part 22 attractingly contacting first attraction part 12. Yoke 23 is preferably larger than second attraction part 22. This configuration suppresses leakage of magnetic force from the lower surface of second attraction part 22. The magnetic force of the magnet of second attraction part 22 can be reduced accordingly, and thus, the size of second attraction part 22 can reduces accordingly. When power generation device 100 is placed on a magnetic body, the above configuration suppresses unintended attraction of power generation device 100 to the magnetic body caused by the magnetic force of second attraction part 22 leaking outside power generation device 100.

Button 21A of activator 20 does not necessarily protrude upward from case 50. The button may protrude downward. In this case, piezoelectric element 11 can vibrate by pulling the button downward.

In order to vertically move activator 20 in power generation device 100, guide holes 21B are provided in body part 21 (activator 20), and guide pins 51A are provided on upper case 51 (case 50). However, the arrangement of the guide holes and the guide pins may be reversed. For example, the guide holes may be provided in activator 20, and guide pins may be provided on case 50. Alternatively, guide pin 51A does not necessarily pass through guide hole 21B. Guide pin 51A may be inserted to a middle of guide hole 21B. In this case, guide hole 21B is not necessarily a through-hole, and may have a bottom.

In power generation device 100, piezoelectric element 11 has a flat plate shape. However, a portion of piezoelectric element 11 may be bent. Still more, piezoelectric element 11 has a cantilever structure, but may have both ends fixed. In this case, first attraction part 12 is attached to the center of piezoelectric element 11, and the center of piezoelectric element 11 is warped by second attraction part 22. Still more, the metal sheet configuring power generator 10 is not necessarily made of nonmagnetic material, such as stainless steel. The metal sheet may be made of magnetic material. In this case, second attraction part 22 is preferably a magnet. This structure allows the metal sheet configuring piezoelectric element 11 to function as first attraction part 12. Still more, piezoelectric element 11 and first attraction part 12 may be unitarily formed in power generator 10. For example, first attraction part 12 may be formed on a portion of metal sheet configuring piezoelectric element 11. Still more, first attraction part 12 may also function as a flange for stabilizing vibration of piezoelectric element 11.

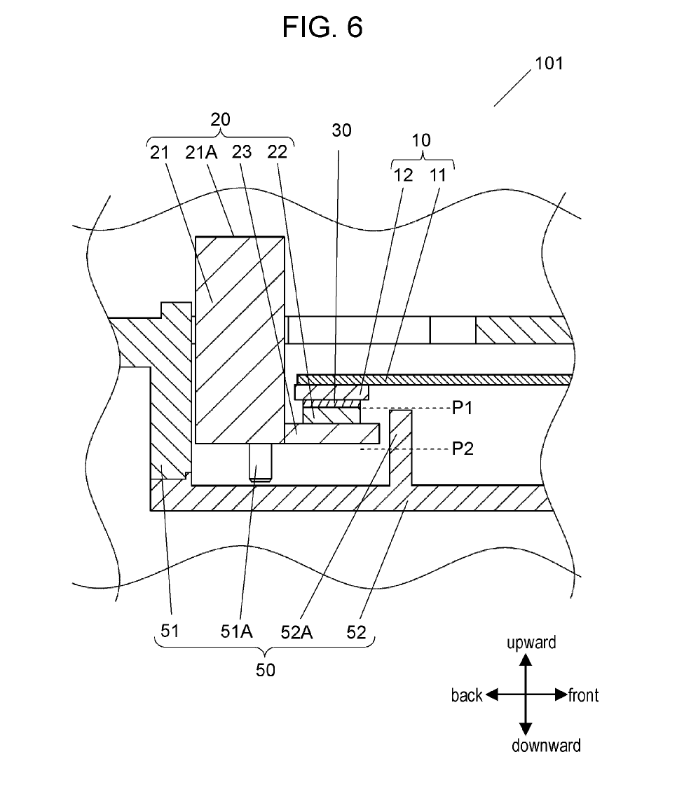

The power generation device of the present disclosure may include cushioning part 30 on at least the lower surface of first attraction part 12 or the upper surface of second attraction part 22, as shown in power generation device 101 shown in FIG. 6. The structure of power generation device 101 will be briefly described below. Power generation device 101 has a structure in which cushioning part 30 is added to power generation device 100. In other words, other components are the same as power generation device 100, and thus same reference marks are given to omit their duplicate description.

FIG. 6 illustrates a modification example of power generation device 100 of the present disclosure. Power generation device 101 shown in FIG. 6 includes cushioning part 30 provided between first attraction part 12 and second attraction part 22. Cushioning part 30 is a sheet member with shock absorbency, and is bonded on the upper surface of second attraction part 22. Cushioning part 30 may be bonded on the lower surface of first attraction part 12. Cushioning part 30 has a thickness not disturbing the attractingly contacting between first attraction part 12 and second attraction part 22. This structure prevents direct collision of second attraction part 22 with first attraction part 12 when second attraction part 22 moved to second position P2 returns to first position P1. This configuration suppresses undesired operation sound (abnormal sound) that is generated by the collision of second attraction part 22 and first attraction part 12.

### INDUSTRIAL APPLICABILITY

A power generation device according to the present disclosure described above has an advantage of a small size, and is effectively applicable to power generation devices of electronic apparatuses that do not require batteries.

### REFERENCE MARKS IN THE DRAWINGS

10 power generator
11 piezoelectric element
12 first attraction part
20 activator
21 body part
21A button
21B guide hole
22 second attraction part
23 yoke
30 cushioning part
50 case
51 upper case
1A guide pin
52 lower case
52A limiter
100, 101 power generation device

1. A power generation device comprising:
a power generator including a piezoelectric element and a first attraction part provided on the piezoelectric element, the piezoelectric element being configured to generate electric power due to vibration; and
an activator including a second attraction part configured to attractingly contact the first attraction part by a magnetic attraction force so as to warp the piezoelectric element by moving from a first position to a second position, the first position being a position at which the second attraction part attractingly contacts the first attraction part,
wherein the piezoelectric element warped by the activator vibrates when attractingly contacting between the first attraction part and the second attraction part is released,
wherein the second attraction part moves to the second position separated away from the first attraction part when the attractingly contacting between the first attraction part and the second attraction part is released, and
wherein the second attraction part moved to the second position returns to the first position by the magnetic attraction force while the first attraction part and the second attraction part are separated away from each other.

2. The power generation device of claim 1,
wherein the activator moves the second attraction part from the first position to the second position by receiving an external load, and
wherein the second attraction part moved to the second position returns to the first position when the external load applied to the activator is released.

3. The power generation device of claim 1, wherein one of the first attraction part and the second attraction part is a magnet, and another of the first attraction part and the second attraction part is made of magnetic material.

4. The power generation device of claim 1, wherein both of the first attraction part and the second attraction part are magnets.

5. The power generation device of claim 1,
wherein the activator has a body part holding the second attraction part, and
wherein the body part is made of resin material.

6. The power generation device of claim 1,
wherein the second attraction part is a magnet,
wherein the activator includes a yoke configured to attractingly contact the second attraction part, and
wherein the yoke is disposed at a surface of the second attraction part opposite to a surface of the second attraction part configured to attractingly contact the first attraction part.

7. The power generation device of claim 1, further comprising a limiter configured to restrict a warpage of the piezoelectric element by contacting the piezoelectric element warped by the activator.

8. The power generation device of claim 1, wherein at least one of the first attraction part and the second attraction part includes a cushioning part provided between the first attraction part and the second attraction part.
